(19) United States
(12) Patent Application Publication
(10) Pub. No.: US 2024/0180013 A1
(43) Pub. Date: May 30, 2024

(54) APPARATUS FOR MANUFACTURING ORGANIC LIGHT EMITTING DIODE FOR LIGHTING

(71) Applicant: LOTI CO., LTD., Hwaseong-si, Gyeonggi-do (KR)

(72) Inventors: Woobin IM, Hongseong-gun, Chungcheongnam-do (KR); Uisoo JUN, Suwon-si, Gyeonggi-do (KR); Jungeun SEO, Daejeon (KR)

(21) Appl. No.: 17/791,884

(22) PCT Filed: Dec. 14, 2020
(86) PCT No.: PCT/KR2020/018227

§ 371 Date: Aug. 5, 2022

(30) Foreign Application Priority Data
Jan. 10, 2020 (KR) 10-2020-0003744

(51) Int. Cl. H10K 71/16; C23C 14/04; C23C 14/24; C23C 14/54; C23C 14/56

(52) U.S. Cl. CPC H10K 71/164; C23C 14/042; C23C 14/24; C23C 14/545; C23C 14/562; H10K 71/166

(57) ABSTRACT

Provided is an apparatus for manufacturing an organic light-emitting device for illumination, including: a supply and deposition unit that supplies a strip-shaped base having base through-holes formed at a predetermined interval at opposite end parts in a widthwise direction, and recovers laminated shadow masks while discharging vaporized materials from deposition sources provided at a plurality of positions to perform sequential deposition; track moving units that are respectively disposed within deposition ranges of the supply and deposition unit, are disposed below the base to be engaged with the base and to move therewith, are provided in the form of a caterpillar that converts a rotational motion into a linear motion at each of the plurality of deposition positions, and have track protrusions formed on an outer periphery thereof to be inserted into the base through-holes; a track driving unit that is disposed at both ends of the track moving units in a lengthwise direction, and provides a rotational force to be converted for movement of the track moving units; a tension adjusting unit that is disposed on upper and lower sides of each track moving unit under movement to adjust the tension of the track moving unit; and a control unit that is provided to measure the movement speed and the tension of the track moving unit to control the driving speed of the track driving unit and the tension of the tension adjusting unit.

### FIELD

The present inventive concept relates to an apparatus for manufacturing an organic light emitting diode for illumination, and more particularly to, an apparatus for manufacturing an organic light emitting diode for illumination, having an improved base movement structure in a deposition device in a manufacturing process of the organic light emitting diode, capable of adjusting a tension while the base is moving with opposite sides thereof being supported to prevent sagging to increase a movement speed and improve a manufacturing efficiency.

### BACKGROUND

In general, an organic light emitting diode (OLED) is a self-luminous device that generates light by recombination of electrons and holes in an organic light emitting layer.

In a case where a current is applied to an OLED device, molecular excitons that are recombined in the light emitting layer exist in two forms of singlet excitons and triplet exitons. Here, the singlet excitons with high energy states correspond to 25% of molecular excitons, and the triplet excitons with low energy states correspond to 75% of the molecular excitons. The singlet excitons and triplet excitons return to a low-energy ground state to disappear while generating light (photons) or emitting heat. Here, a case where light is generated by the singlet excitons is called fluorescence, and a case where light is generated by the triplet excitons is called phosphorescence.

In the case of fluorescent organic materials, only 25% of excitons contribute to light generation, and in the case of phosphorescent organic materials, light is generated by the triplet excitons corresponding to 75% of excitons. The singlet excitons corresponding to the remaining 25% also contribute to the generation of light through energy transfer to the triplet excitons through an intersystem crossing (ISC) pathway, so that 100% of the excitons contribute to light energy.

Since OLED was implemented in 1987, commercial products have been proposed in display and lighting fields by making rapid progress through organic material development, organic material improvement, charge transport improvement, transparent electrode improvement, light extraction structure development, and the like. In particular, as the use of incandescent lamps and fluorescent lamps is regulated due to energy saving promotion measures, OLED light sources are in the spotlight.

Further, since the OLED light sources do not employ heavy metals such as mercury and lead, the OLED light sources are eco-friendly.

A vacuum deposition method and a coating method are generally known as a method for manufacturing the OLED. The vacuum deposition method has been mainly used in that the purity of constituent layer-forming materials can be increased and OLEDs having a long life can be manufactured.

In such a vacuum deposition method, constituent layers are formed by performing deposition using deposition sources provided at positions opposite to a base in a vacuum chamber. In the conventional OLED production process, the OLED is manufactured using a large flat glass substrate to enlarge the size of the device, which causes increase in the investment cost of facilities such as a device or a clean room and the manufacturing cost. In consideration of price competitiveness of lighting products, the key is to produce a large amount of products in a small clean room space. To this end, a roll process has been employed in the OLED production process. The roll process is a process of continuously depositing constituent layers on a base while moving the base by continuously unwinding the base wound up in the form of a roll on one side and rewinding the unwound base on the other side.

In the roll process, in a case where deposition sources are disposed above the base and vaporized materials are discharged down toward the base from the deposition sources to form constituent layers, foreign substances such as dust may fall from the deposition sources and adhere to the base to be mixed in an organic device. In a case where the foreign substances are mixed in the organic EL device, light emission is adversely affected.

Accordingly, in order to suppress the mixing of the foreign substances, the deposition sources are positioned below the base. However, since the organic light emitting diode is formed by stacking a plurality of constituent layers, in a case where all the constituent layers are to be sequentially formed by deposition from below, it is necessary to move the base so as to pass above all deposition sources.

In this case, since a region of the base passing through the deposition sources becomes long, it is difficult to apply sufficient tension to the base, so that the base tends to warp or vibrate. In a case where a deposition surface of the base and the deposition sources come into contact with each other due to warpage or vibration of the base, the base or the constituent layers formed on the base may be damaged.

Further, in a case where the distance between the base and the deposition source changes, it is difficult to appropriately control the thickness of the constituent layers, and there is a concern that constituent layers having desired light emitting characteristics may not be obtained. In addition, in a case where the amount of tension is increased to provide a sufficient tension to the base, in the case of a flexible base, a stretching force acts on the base to stretch and deform the base, and thus, it may be difficult to form a deposition membrane in a desired region.

Further, in a case where the roll process is performed using thin glass, an excessive amount of tension may cause damage to a substrate, thereby making it difficult to manufacture a desired product.

In recent years, an apparatus that performs a linear motion during a deposition operation, in which a plurality of through-holes are formed to be spaced apart from each other at a predetermined interval in the width direction of the base, and a rotator that has a plurality of protrusions inserted into the through-holes on the outer periphery thereof and is rotated by an operation of a motor is provided at a plurality of positions, a tension maintaining body that has a plurality of protrusions inserted into the through-holes on the outer periphery thereof and is supported to be rotatable is provided to maintain a tension between the rotators, has been developed and used.

However, the conventional apparatus for manufacturing an organic light emitting diode for illumination has a problem in that the power of the rotator is directly transmitted to the through-holes of the base, which causes damage to the base due to the transmission of the moving force.

Further, since the plurality of rotatably supported tension maintaining bodies should be provided to maintain the tension during movement in the deposition device, the apparatus becomes complicated, and in the case of being stopped or warped when the apparatus is rotated in a state where the base is continuously engaged and supported while moving at plural locations in a deposition environment, the base may be damaged.

### SUMMARY

In order to solve the above, an object of the present inventive concept is to provide an apparatus for manufacturing an organic light emitting diode, having an improved base movement structure in a deposition device in a manufacturing process of the organic light emitting diode, capable of improving a manufacturing efficiency by accurately maintaining a movement speed while minimizing damage of a base as the base is moved while being engaged with and supported on a track of a caterpillar that converts a rotational motion into a linear motion in a state where both side surfaces of the base are supported in the deposition device, and simplifying the structure to reduce the maintenance cost.

Objects of the present inventive concept are not limited to the objects mentioned above, and other objects not mentioned will be clearly understood from the description below.

In order to achieve the above object, there is provided an apparatus for manufacturing an organic light emitting diode (OLED) for illumination, including: a supply and deposition unit that supplies a strip-shaped base having base through-holes formed at a predetermined interval at opposite end parts in a widthwise direction, and recovers laminated shadow masks while discharging vaporized materials from deposition sources provided at a plurality of positions to perform sequential deposition: track moving units that are respectively disposed within deposition ranges of the supply and deposition unit, are disposed below the base to be engaged with the base and to move therewith, are provided in the form of a caterpillar that converts a rotational motion into a linear motion at each of the plurality of deposition positions, and have track protrusions formed on an outer periphery thereof to be inserted into the base through-holes; a track driving unit that is disposed at both ends of the track moving units in a lengthwise direction, and provides a rotational force to be converted for movement of the track moving units: a tension adjusting unit that is disposed on upper and lower sides of each track moving unit under movement to adjust the tension of the track moving unit: and a control unit that is connected to the track moving units and the tension adjusting units to control the movement and the tension.

Further, the supply and deposition unit may include: a base supply unit that supplies the base formed by lamination of a substrate, a support film, and the plurality of shadow masks to the track moving units for deposition: the deposition sources disposed at the plurality of positions that are configured to discharge the vaporized materials for the respective deposition steps to perform the sequential deposition: and a mask recovery unit that is disposed on a lower side between the plurality of deposition sources and is configured to recover each of the plurality of shadow masks that have completed the deposition in each stage.

Further, the track moving unit may include: a track body that is disposed in a movement range for each deposition step of the supply and deposition unit, is provided in the form of a caterpillar that moves in the lengthwise direction, and has track insertion holes that are formed in the form of plural through-holes spaced at a predetermined interval in the lengthwise direction to communicate with the base through-holes and are engaged with the track driving unit: and the track protrusions that protrude at a plurality of positions at a predetermined interval on the outer surface of the track body, are disposed between the track insertion holes, and are engaged with the base through-holes to move together.

Further, the track driving unit may include: a track driving rotator that is disposed on one end side of the track moving unit in the lengthwise direction, has driving rotational protrusions that protrude in a radial manner on the outer periphery thereof and are inserted into and engaged with the track moving unit that communicates with the base through-holes, and is rotated for the conversion to the linear motion: a track driven rotator that is disposed on the other end side of the track moving unit in the lengthwise direction, which is a position opposite to the track driving rotator, has driven rotational protrusions that protrude in a radial manner on the outer periphery thereof and are inserted into and engaged with the track moving unit that communicates with the base through-holes, and supports the rotation of the track driven rotator; and a drive motor that is connected to one side of the track driving rotator, and supplies rotational power to the track driving rotator.

Further, the apparatus may further include: a driving gear rotator that is connected to one side of each of the plurality of track driving rotators, receives the rotational power, and rotates together with the track driving rotator: a driving shaft that is connected to the drive motor to transmit the rotational power of the drive motor, and is provided to pass through one side of the plurality of track driving rotators: and a driving gear that is connected to the driving shaft at a plurality of positions to secure the same rotational speed, and is gear-engaged with the driving gear rotator to transmit the rotational power of the drive motor to the plurality of track driving rotators.

Further, the tension control unit may include: an upper support roller that is disposed at a plurality of positions spaced at a predetermined interval in an upper part of the caterpillar of the track moving unit under movement, and supports a lower side of the track moving unit that moves in a state of being engaged with the base to prevent sagging: a down-regulating roller that is disposed in a lower part of the caterpillar of the track moving unit under movement, and presses an upper side of the track moving unit downward to adjust the tension according to change in the tension: a down-regulating cylinder that is disposed above the down-regulating roller, and provides power for moving the down-regulating roller up and down according to the tension measured by the control unit: an up-regulating roller that is disposed below the caterpillar of the track moving unit under movement, presses an upper side of the track moving unit upward to adjust the tension according to change in the tension, includes an up-regulating groove into which the track protrusions of the track moving unit engaged with the base are inserted at a central portion thereof: and an up-regulating cylinder that is disposed below the up-regulating roller, and provides power for moving the up-regulating roller up and down according to the tension measured by the control unit.

Further, the apparatus may further include: an upper press roller that is disposed on the upper side of the caterpillar of the track moving unit under movement, is disposed above the upper support roller to press the upper side of the base of which the lower side is supported by the upper support roller, and has a press groove into which the track protrusions of the track moving unit inserted into the base are inserted at a central portion thereof.

In addition, the control unit may include: a deposition movement speed sensor that is disposed on one side of the track moving unit under movement, and is provided to sense a movement speed of the base in each deposition step: a tension sensor that is disposed on one side of the track moving unit under movement, and is provided to sense the tension on a movement path of the caterpillar: and a control body that receives signals from the deposition movement speed sensor and the tension sensor, compares a predetermined speed for each deposition with the movement speed measured by the deposition movement speed sensor to control the track driving unit, and compares the tension value measured by the tension sensor with a predetermined tension value to control the tension control unit.

Further, the apparatus may further include: a sagging prevention unit that is disposed above the track driving unit to prevent sagging of the base.

In addition, the sagging prevention unit may be disposed on the lower surface of the base, may be located at each of opposite ends in the width direction around the base through-holes with which the track driving unit is engaged, and may be made of a film adhesive that adheres to the upper surface of the track moving unit to prevent sagging.

Further, the sagging prevention unit may include: a metal strip that is disposed on the upper surface of the base at a central portion and both sides thereof in the width direction, and is made of a metal material for generating an attractive force by a magnetic force: and a magnet body that is disposed above the track moving unit, is provided at a plurality of positions at a predetermined interval in the lengthwise direction, and applies the magnetic force to the metal strip provided on the base under movement to generate the attractive force in the central portion of the base for preventing sagging.

In addition, the sagging prevention unit may include: a metal strip that is disposed on the upper surface of the base at a central portion and both sides thereof in the width direction, and is made of a metal material for generating an attractive force by a magnetic force: a magnetic track body that is disposed in an overlay manner above the track moving unit to be moved in the form of a caterpillar, has magnetic track inserting holes that communicate with the base through-holes at positions spaced at a predetermined interval in the width direction, and is made of a magnetic material to generate an attractive force while moving above the metal strip: and a magnetic track rotator that is disposed above the track driving unit, has magnetic track rotational protrusions that protrude in a radial manner on the outer periphery thereof and are inserted into the magnetic track insertion holes, and rotationally moves the caterpillar of the magnetic track body.

Specific details for achieving the above object will become clear with reference to the embodiments described below in detail in conjunction with the accompanying drawings.

However, the present inventive concept is not limited to the embodiments disclosed below, and may be configured in a variety of different forms, and these embodiments allow the disclosure of the present inventive concept to be complete and provide to fully inform the scope of the inventive concept of those skilled in the art in the technical field to which the present inventive concept belongs.

According to the present inventive concept, it is possible to provide an apparatus for manufacturing an organic light emitting diode, in a deposition device in a manufacturing process of the organic light emitting diode, capable of improving a deposition efficiency by accurately maintaining a movement speed while minimizing damage of a base as the base is moved while being engaged with and supported on a track of a caterpillar that converts a rotational motion into a linear motion in a state where both side surfaces of the base are supported in the deposition device, and simplifying the structure to reduce the maintenance cost.

### BRIEF DESCRIPTION OF DRAWINGS

FIG. 1 is a block diagram showing an apparatus for manufacturing an organic light emitting diode for illumination according to an embodiment of the present inventive concept.

FIG. 2 is an exploded perspective view partially showing a base and a track moving unit, which are main parts of the apparatus for manufacturing the organic light emitting diode for illumination in FIG. 1.

FIG. 3 is a diagram showing a configuration of a main part of the apparatus for manufacturing the organic light emitting diode for illumination in FIG. 1.

FIG. 4 is a diagram showing an operating state of the apparatus for manufacturing the organic light emitting diode for illumination in FIG. 3.

FIG. 5 is a diagram showing a state in which a tension of the apparatus for manufacturing the organic light emitting diode for illumination in FIG. 3 is adjusted.

FIG. 6 is a control block diagram showing a control configuration of the apparatus for manufacturing the organic light emitting diode for illumination in FIG. 1.

FIG. 7 is a partial sectional view showing an apparatus for manufacturing an organic light emitting diode for illumination according to another embodiment of the present inventive concept.

FIG. 8 is a partial sectional view showing a sagging prevention unit that is a main part of an apparatus for manufacturing an organic light emitting diode for illumination according to still another embodiment of the present inventive concept.

FIG. 9 is a partial sectional view showing a sagging prevention unit that is a main part of an apparatus for manufacturing an organic light emitting diode for illumination according to yet still another embodiment of the present inventive concept.

### DETAILED DESCRIPTION

Hereinafter, embodiments of the present inventive concept will be described in detail with reference to the accompanying drawings so that those skilled in the art can easily carry out the present inventive concept. The present inventive concept may be embodied in different forms, and thus, is not limited to the embodiments described herein. Further, in the drawings, for clarity of description of the inventive concept, configurations irrelevant to the description are omitted, and similar reference numerals are attached to similar components throughout the specification.

Further, components given the same name may be denoted by different numbers in different drawings as necessary. The reference numerals are only used for the convenience of description, and do not limit the concept, features, functions or effects of respective components.

Throughout the specification, in a case where a component is “connected” with another component, this includes not only the case of being “directly connected” but also the case of being “electrically connected” in an indirect manner. Further, in a case where a component “includes” a sub-component, it means that another sub-component may be further included, unless otherwise stated, and it is to be understood that existence or addition of one or more other features, numbers, steps, operations, components, parts, or combinations thereof is not excluded in advance.

Throughout the specification, the term “organic” includes polymeric materials as well as small molecule organic materials that can be used to manufacture organic optoelectronic devices.

Throughout the specification, in a case where a unit “includes” a sub-component, it means that another sub-component may be further included, unless otherwise stated. The terms “about”, “substantially”, or the like used to express “degree” throughout the specification are used, in a case where numerical values or tolerances for manufacturing and materials inherent in stated meanings are given, to represent the numerical values or numerical values close to the numerical values, which are used to prevent an unscrupulous infringer from using the disclosure in which accurate or absolute numerical values are given for understanding of the inventive concept. The term “step of” used to express “process” throughout the specification does not mean “step for”.

Hereinafter, an embodiment of the present inventive concept will be described in detail with reference to the accompanying drawings.

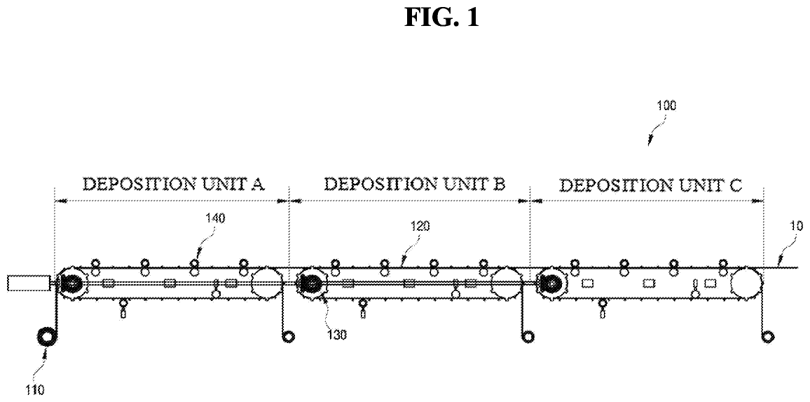

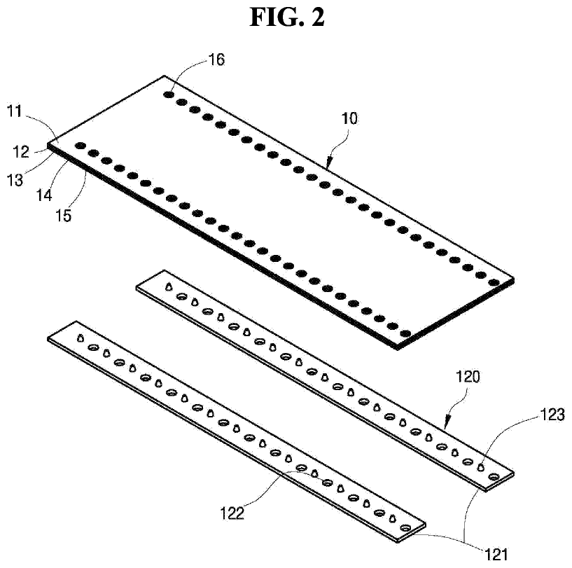

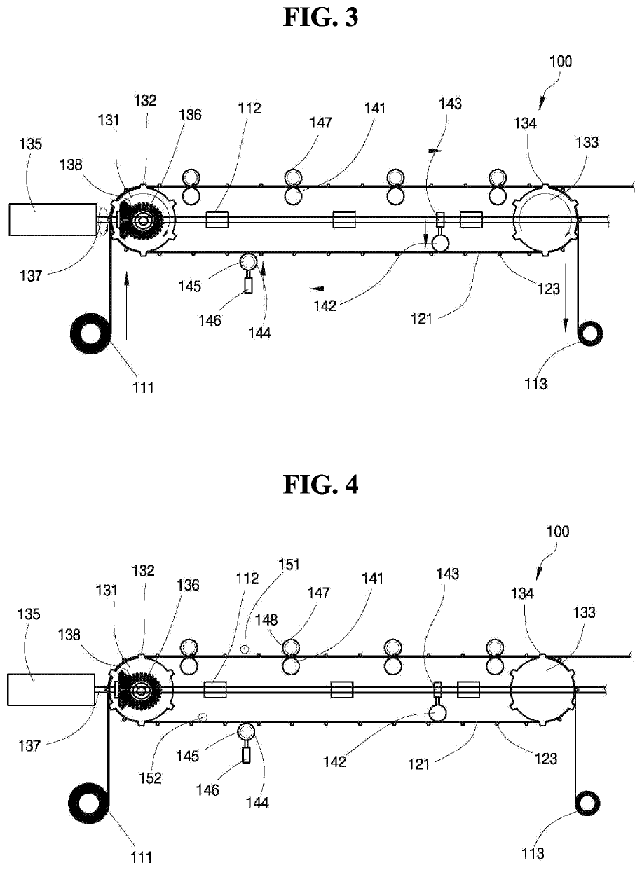

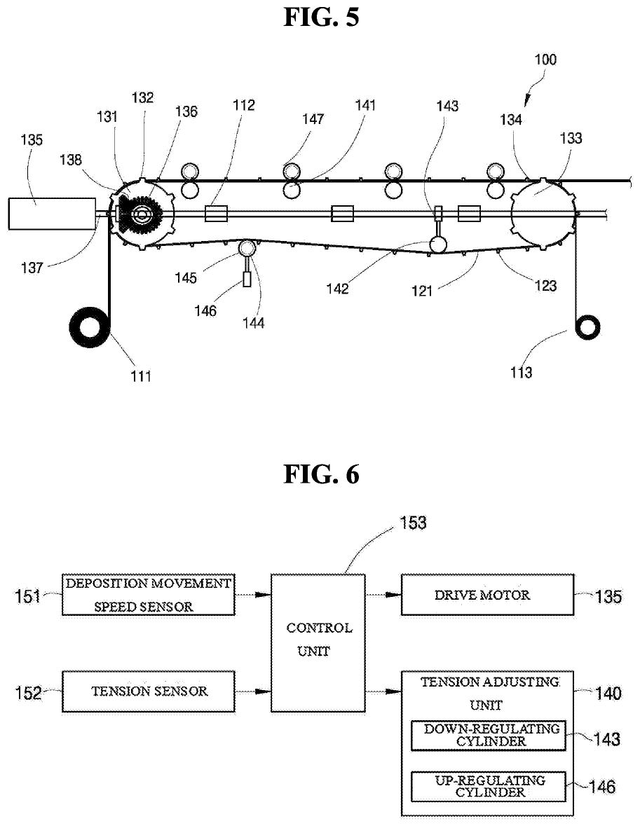

FIG. 1 is a diagram showing a configuration of an apparatus for manufacturing an organic light emitting diode for illumination according to an embodiment of the present inventive concept, FIG. 2 is an exploded perspective view partially showing a base and a track moving unit, which are main parts of the apparatus for manufacturing the organic light emitting diode for illumination in FIG. 1, FIG. 3 is a diagram showing a configuration of a main part of the apparatus for manufacturing the organic light emitting diode for illumination in FIG. 1, FIG. 4 is a diagram showing a configuration of an operating state of the apparatus for manufacturing the organic light emitting diode for illumination in FIG. 3, FIG. 5 is a diagram showing a state in which a tension of the apparatus for manufacturing the organic light emitting diode for illumination in FIG. 3 is adjusted, and FIG. 6 is a control block diagram showing a control configuration of the apparatus for manufacturing the organic light emitting diode for illumination in FIG. 1.

Referring to FIGS. 1 to 6, a manufacturing apparatus 100 according to an embodiment of the present inventive concept is configured to manufacture an organic light emitting diode for illumination from a strip-shaped base 10 by deposition while moving the base 10 in a lengthwise direction.

As shown in FIG. 1, the manufacturing apparatus 100 includes deposition units A, B, and C that sequentially perform deposition by discharging vaporized materials from deposition sources provided below the base 10 in a lengthwise direction, and a track moving unit 120 that moves the base in the lengthwise direction.

First, the base 10 has a strip shape in which base through-holes 16 are formed at a predetermined interval at opposite end parts in a width direction. The base 10 is made of a plurality of layers that are closely contacted and/or laminated, and is supplied to the deposition units A to C by a base supply unit 111 provided with a base supply device. Here, the base supply device may be, for example, an unwinder that unwinds the strip-shaped base 10 wound in a roll shape. The base 10 will be described in detail with reference to FIGS. 2 and 3.

As the deposition units A to C, the deposition unit A that deposits an organic material, the deposition unit B that deposits a cathode material, and the deposition unit C that deposits an encapsulation material according to a thin film encapsulation (TFE) method or a hybrid method are sequentially disposed along the movement direction of the base 10. The deposition units A to C each include a deposition source 112 below the moving base 10. As a deposition surface of the base 10 is directed downward, the deposition units A to C perform deposition by discharging vaporized materials from the deposition sources 112 onto the deposition surface.

Each deposition source 112 may be disposed so that an opening thereof faces the deposition surface of the base 10. Each deposition source 112 includes a heater (not shown), and the heater heats and vaporizes the material contained in each deposition source, and discharges the vaporized material upward through the opening. The number of the deposition sources 112 disposed in each of the deposition units A to C may be one or more depending on the number of layers to be formed, and is not limited to the embodiment of FIG. 1.

Further, since each deposition source 112 is disposed below the base 10, it is possible to prevent the base 10 from being contaminated by particles scattered from the deposition source 112. Furthermore, as necessary, a configuration in which the deposition source is disposed on the side of the base 10 to minimize contamination due to particles may be employed. In this case, the base 10 may be implemented to move in the lengthwise direction in a vertically standing state.

Further, although not shown in FIG. 1, the manufacturing apparatus 100 includes a plurality of vacuum chambers. In each vacuum chamber, the base supply unit 111, the deposition unit A, the deposition unit B, the deposition unit C, and the track moving unit 120 are disposed. The inside of each vacuum chamber is made into a pressure-reduced state by a vacuum generator to form a vacuum region therein. Further, adjacent vacuum chambers communicate with each other through openings while maintaining vacuum states. In addition, the base 10 may be sequentially moved from the base supply unit 111 through an opening by operation of a rolling driver 5. Specifically, the base 10 unwound from the base supply unit 111 is moved to the deposition unit A, the deposition unit B, and the deposition unit C.

FIG. 2 shows a configuration of the base 10 according to the embodiment of the present inventive concept. As shown in FIG. 2, the base 10 is configured by sequentially adhering and/or bonding a plurality of materials, and specifically, may include an anodized (for example, ITO (Indium Tin Oxide) coated) substrate 12, a support film 11 disposed on the substrate 12 to support the substrate 12, and a plurality of shadow masks 13, 14, and 15 disposed under the substrate 12.

Here, the substrate 12 may be a glass substrate or a film, but is not limited thereto.

Further, the plurality of shadow masks 13, 14, and 15 include an encapsulation shadow mask 13 used in the deposition unit C, a cathode shadow mask 14 used in the deposition unit B, and an organic shadow mask 15 used in the deposition unit A, in which the shadow masks 13, 14 and 15 are sequentially disposed in a reverse order of a use order along the movement direction of the base 10, that is, the shadow mask (for example, the encapsulation shadow mask 13) to be used last is disposed above and the remaining shadow masks (the cathode shadow mask 14 and the organic shadow mask 15) are sequentially disposed under the shadow mask 13.

Further, the shadow masks 13, 14, and 15 are sequentially separated and recovered by a mask recovery unit 113 provided with a mask recovery device disposed at a terminal of each of the deposition units A to C. Here, the mask recovery device may be a winder, but is not limited thereto.

On the other hand, the width, thickness, and length of the base 10 may be variously set according to the size of the substrate for the organic light emitting diode to be formed on the base 10.

The configuration in which the number of shadow masks recovered from the above-described apparatus for manufacturing the organic light emitting diode for illumination is three and the number of deposition sources are three according to the number of shadow masks is presented as an example, and the present inventive concept is not limited thereto. Here, the main configuration of the present inventive concept will be described below.

The base 10 is formed with the base through-holes 16 at a predetermined interval at the opposite ends in the width direction.

The base having the base through-holes 16 is supplied from the supply and deposition unit 110, is moved by the track moving unit 120 driven by a track driving unit 130, and is subjected to deposition while the speed and tension of the track moving unit 120 is being controlled by controlling the operation of the track driving unit 130 and a tension adjusting unit 140.

The supply and deposition unit 110 is configured to supply the strip-shaped base having the base through-holes 16 formed at a predetermined interval at opposite end parts in a widthwise direction, to perform sequential deposition while discharging vaporized materials from the deposition sources 112 provided at the plurality of positions, and to recover the shadow masks 13, 14, and 15 that are laminated.

Referring to FIGS. 3 to 6, the supply and deposition unit 110 includes the base supply unit 111, the deposition sources 112, and the mask recovery unit 113.

The base supply unit 111 supplies the base 10 formed by lamination of the substrate, the support film and the plurality of shadow masks 13, 14, and 15 to the track moving unit 120 for deposition.

The deposition sources 112 disposed at the plurality of positions are configured to discharge the vaporized materials for the respective deposition steps to perform sequential deposition.

The mask recovery unit 113 is disposed below each of the plurality of deposition units, and is configured to recover each of the plurality of shadow masks 13, 14, and 15 that have completed the deposition in each stage.

The track moving unit 120 is disposed in the deposition range of the supply and deposition unit 110, is disposed below the base 10 to be engaged with the base and moved together, is provided in the form of a caterpillar that converts a rotational motion into a linear motion in each of the plurality of deposition positions, and has track protrusions 123 that are respectively inserted into the base through-holes 16 on the outer surface thereof.

The track moving unit 120 includes a track body 121, and the track protrusions 123.

The track body 121 is disposed in a movement range for each deposition step of the supply and deposition unit 110, is provided in the form of the caterpillar that moves in the lengthwise direction, and has track insertion holes 122 that are formed in the form of plural through-holes spaced at a predetermined interval in the lengthwise direction to communicate with the base through-holes 16 and are engaged with the track driving unit 130.

The track protrusions 123 protrude at a plurality of positions at a predetermined interval on the outer surface of the track body 121, are disposed between the track insertion holes 122, and are engaged with the base through-holes 16 to move together.

That is, the track body 121 converts the rotational motion of the track driving unit 130 into the linear motion using the caterpillar shape that forms a closed curve, which is provided in the form of a belt in the drawings, but this is for convenience of description. It is apparent to those skilled in the art that a driving mechanism such as a chain may be used instead of the belt.

Further, the track protrusions 123 and the track insertion holes 122 are alternately provided to support the lower surface of the base, in which the track protrusions 123 are inserted into the base through-holes 16 of the base located above the track body 121, and the track insertion holes 122 are provided to communicate with the base through-holes 16.

The track driving unit 130 is disposed at both ends of the track body 121 in the lengthwise direction, and provides a rotational force that is converted to a linear motion to move the track moving unit 120.

The track driving unit 130 includes a track driving rotator 131, a track driven rotator 133, a drive motor 135, a driving gear rotator 136, a driving shaft 137, and a driving gear 138.

The track driving rotator 131 is disposed on one end side of the track body 121 in the lengthwise direction, and has driving rotational protrusions 132 that protrude in a radial manner on the outer periphery thereof and are inserted into and engaged with the track insertion holes 122 that communicate with the base through-holes 16.

The track driven rotator 133 is disposed on the other end side of the track body 121 in the lengthwise direction, which is a position opposite to the track driving rotator 131, has driven rotational protrusions 134 that protrude in a radial manner on the outer periphery thereof and are inserted into and engaged with the track insertion holes 122 that communicate with the base through-holes 16, and supports the rotation of the track driven rotator 133.

The drive motor 135 is connected to one side of the track driving rotator 131, and supplies rotational power to the track driving rotator 131.

That is, the drive motor 135 and the track driving rotator 131 may be directly connected to each other in each deposition stage, but a bevel gear connection method to be described below may be used to secure the same speed at the plurality of positions.

The driving gear rotator 136 that is a gear receives the rotational power is connected to one side of each of the plurality of track driving rotators 131, and rotates together with the track driving rotator 131.

The driving shaft 137 is connected to the drive motor 135 to transmit the rotational force of the drive motor 135, and is provided to pass through one side of the plurality of track driving rotators 131.

The driving gear 138 is connected to the driving shaft 137 at the plurality of positions to secure the same rotational speed, and is gear-engaged with the driving gear rotator 136 to transmit the rotational force of the drive motor 135 to the plurality of track driving rotators 131.

The tension adjusting unit 140 is disposed on upper and lower sides of the track body 121 to adjust the tension of the track body 121 under movement.

The tension adjusting unit 140 includes an upper support roller 141, a down-regulating roller 142, a down-regulating cylinder 143, an up-regulating roller 144, an up-regulating cylinder 146, and an upper press roller 147.

The upper support roller 141 is disposed at a plurality of positions spaced at a predetermined interval in an upper part of the caterpillar of the track body 121, and supports a lower side of the track body 121 that moves in a state of being engaged with the base 10 to prevent sagging.

The down-regulating roller 142 is disposed in a lower part of the caterpillar of the track body 121 under movement, and presses an upper side of the track body 121 downward to adjust the tension change in the tension.

The down-regulating cylinder 143 is disposed above the down-regulating roller 142, and provides power for moving the down-regulating roller 142 up and down according to the tension measured by the control unit 150.

The up-regulating roller 144 is disposed below the caterpillar of the track body 121 under movement, presses an upper side of the track body 121 upward to adjust the tension according to change in the tension, includes an up-regulating groove 145 into which the track protrusions 123 of the track moving unit 120 engaged with the base are inserted at a central portion thereof.

The up-regulating cylinder 146 is disposed below the up-regulating roller 144, and provides power for moving the up-regulating roller 144 up and down according to the tension measured by the control unit 150.

The up-regulating roller 144 and the down-regulating roller 142 are disposed to be spaced from each other at a predetermined interval on the lower side of the track body 121 in a state where the track body 121 completes the movement of the base and then passes through the track driven rotator 133, so that the control unit 150 can operate the up-regulating cylinder 144 and the down-regulating cylinder 143 to effectively control the tension while pressing them up and down.

The upper press roller 147 is disposed on the upper side of the caterpillar of the track body 121, is disposed above the upper support roller 141 to press the upper side of the base of which the lower side is supported by the upper support roller 141, and has a press groove 148 into which the track protrusions 123 of the track body 121 inserted into the base are inserted at a central portion thereof.

That is, the upper support roller 141 is provided to press the upper part of the base moving in the lengthwise direction with the upper part opened to prevent separation, and the press groove 148 for minimizing movement interference through engagement with the track protrusions 123 is formed at the central portion thereof.

The control unit 150 is provided to measure the movement speed and the tension of the track moving unit 120 to control the driving speed of the track driving unit 130 and the tension of the tension adjusting unit 140.

The control unit 150 includes a deposition movement speed sensor 151, a tension sensor 152, and a control body 153.

The deposition movement speed sensor 151 is disposed on one side of the track body 121 under movement, and is provided to sense the movement speed of the base in each deposition step.

The tension sensor 152 is disposed on one side of the track body 121 under movement, and is provided to sense the tension on a movement path of the caterpillar.

The control body 153 receives signals from the deposition movement speed sensor 151 and the tension sensor 152, compares a predetermined speed for each deposition with the speed measured by the deposition movement speed sensor 151 to control the drive motor 135, and compares the tension value measured by the tension sensor 152 with a predetermined tension value to control the down-regulating cylinder 143 and the up-regulating cylinder 146.

That is, the control body 153 detects the movement speed of the track body 121 using the deposition movement speed sensor 151, and compares the detected speed with the predetermined movement speed to control the movement speed under the control of the rotational speed of the drive motor 135.

Further, the control body 153 compares the tension value of the track body 121 measured using the tension sensor 152 with the predetermined tension value of the track body 121 to control the adjustment cylinder 143 that adjusts the tension while moving downward and the up-regulating cylinder 146 that adjusts the tension while moving upward.

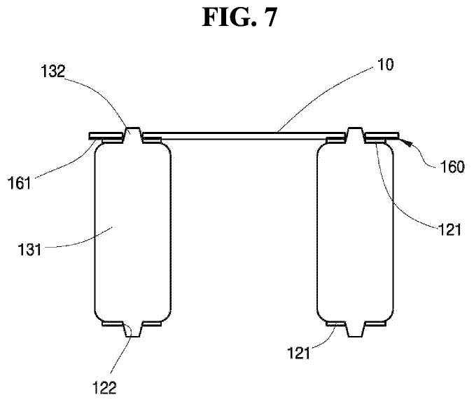

FIG. 7 is a partial sectional view showing an apparatus for manufacturing an organic light emitting diode for illumination according to another embodiment of the present inventive concept.

Referring to FIG. 7, an apparatus 100 for manufacturing an organic light emitting diode for illumination according to another embodiment of the present inventive concept includes a supply and deposition unit 110, a track moving unit 120, a track driving unit 130, a tension adjusting unit 140, a control unit 150, and a sagging prevention unit 160. Here, since the supply and deposition unit 110, the track moving unit 120, the track driving unit 130, the tension adjusting unit 140, and the control unit 150 are the same as in the apparatus 100 for manufacturing the organic light emitting diode for illumination shown in FIGS. 1 to 6, only the different sagging prevention unit 160 will be described as follows.

The sagging prevention unit 160 is disposed above the track driving rotator 131 to prevent sagging of the base 10.

The sagging prevention unit 160 is disposed on the lower surface of the base 10, is located at each of opposite ends in the width direction around the base through-holes 16 into which the driving rotational protrusions 132 are inserted, and is made of a film adhesive 161 that adheres to the upper surface of the track body 121 to prevent sagging.

The film adhesive 161 adheres to the width-directional opposite ends of the track body 121 that supports the base to prevent separation and sagging at the same time.

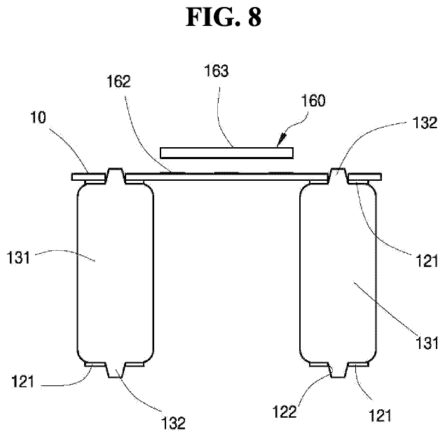

FIG. 8 is a partial sectional view showing a sagging prevention unit that is a main part of an apparatus for manufacturing an organic light emitting diode for illumination according to still another embodiment of the present inventive concept.

Referring to FIG. 8, the sagging prevention unit that is the main part of the apparatus for manufacturing the organic light emitting diode for illumination according to the present embodiment includes a supply deposition unit 110, a track moving unit 120, a track driving unit 130, a tension adjusting unit 140, a control unit 150, and a sagging prevention unit 160. Here, since the supply and deposition unit 110, the track moving unit 120, the track driving unit 130, the tension adjusting unit 140, and the control unit 150 are the same as in the apparatus 100 for manufacturing the organic light emitting diode for illumination shown in FIGS. 1 to 6, the different sagging prevention unit 160 will be described as follows.

The sagging prevention unit 160 includes a metal strip 162 and a magnet body 163.

The metal strip 162 is disposed on the upper surface of the base 10 at a central portion and both sides thereof in the width direction, and is made of a metal material for generating an attractive force by a magnetic force. That is, when the magnetic force acts on the metal strip 162 positioned at the center and both sides in the width direction on the upper surface of the base 10, the metal strip 162 is pulled upward by the attractive force, so that sagging can be prevented.

The magnet body 163 is disposed above the track body 121, is provided at a plurality of positions at a predetermined interval in the lengthwise direction, and applies the magnetic force to the metal strip 162 provided on the base 10 under movement to generate the attractive force in the central portion of the base 10 for preventing sagging.

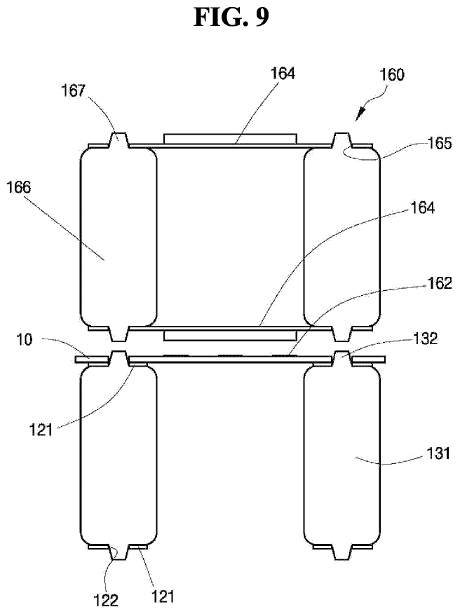

FIG. 9 is a partial sectional view showing a sagging prevention unit that is a main part of an apparatus for manufacturing an organic light emitting diode for illumination according to yet still another embodiment of the present inventive concept.

Referring to FIG. 9, the sagging prevention unit that is the main component of the apparatus for manufacturing the organic light emitting diode for illumination according to the present embodiment includes a supply and deposition unit 110, a track moving unit 120, and a track driving unit 130, a tension adjusting unit 140, a control unit 150, and a sagging prevention unit 160. Here, since the supply and deposition unit 110, the track moving unit 120, the track driving unit 130, the tension adjusting unit 140, and the control unit 150 are the same as in the apparatus 100 for manufacturing the organic light emitting diode for illumination shown in FIGS. 1 to 6, only the different sagging prevention unit 160 will be described as follows.

The sagging prevention unit 160 includes a metal strip 162, a magnetic track body 164, and a magnetic track rotator 166.

The metal strip 162 is disposed on the upper surface of the base 10, is located at a central portion and both sides thereof in the width direction, and is made of a metal material for generating an attractive force by a magnetic force. That is, when the magnetic force acts on the metal strip 162 positioned at the center and both sides in the width direction on the upper surface of the base 10, the metal strip 162 is pulled upward by the attractive force, so that sagging can be prevented.

The magnetic track body 164 is disposed in an overlay manner above the track body 121 to be moved in the form of a caterpillar, has magnetic track inserting holes 165 that communicate with the base through-holes 16 at positions spaced at a predetermined interval in the width direction, and is made of a magnetic material to generate an attractive force while moving above the metal strip 162.

The magnetic track rotator 166 is disposed above the track body 121, has magnetic track rotational protrusions 167 that protrude in a radial manner on the outer periphery thereof and are inserted into the magnetic track inserting holes 165, and rotationally moves the caterpillar of the magnetic track body 164.

The above description is merely illustrative of the technical idea of the present inventive concept, and various modifications and variations will be possible without departing from the essential features of the present inventive concept by those skilled in the art to which the present inventive concept belongs.

Accordingly, the embodiments disclosed above are not intended to limit the technical idea of the present inventive concept, and the scope of the technical idea of the present inventive concept is not limited by these embodiments.

The protection scope of the present inventive concept should be interpreted by the following claims, and equivalent technical ideas should be interpreted as being included in the scope of the present inventive concept.

### DESCRIPTION OF THE REFERENCE NUMERALS

10: Base
11: Support film
12: Substrate
13: Encapsulation shadow mask
14: Cathode shadow mask
15: Organic shadow mask
16: Base through-hole
100: Manufacturing apparatus
110: Supply and deposition unit
111: Base supply unit
112: Mask recovery unit
113: Deposition source
120: Track moving unit
121: Track body
122: Track insertion hole
123: Track protrusion
130: Track driving unit
131: Track driving rotator
132: Driving rotational protrusion
133: Driving shaft
134: Driving rotator
135: Track driven rotator
136: Power transmission medium
140: Tension adjusting unit
141: Upper support roller
142: Down-regulating roller
143: Down-regulating cylinder
144: Up-regulating roller
145: Up-regulating groove
146: Up-regulating cylinder
147: Upper press roller
148: Press groove
150: Control unit
151: Deposition movement speed sensor
152: Tension sensor
153: Control body
160: Sagging prevention unit
161: Film adhesive
162: Metal strip
163: Magnet body
164: Magnetic track body
165: Magnetic track inserting hole
166: Magnetic track rotator
167: Magnetic track rotational protrusion

What is claimed is:

1. An apparatus for manufacturing an organic light emitting diode (OLED) for illumination, comprising:
a supply and deposition unit that supplies a strip-shaped base having base through-holes formed at a predetermined interval at opposite end parts in a widthwise direction, and recovers laminated shadow masks while discharging vaporized materials from deposition sources provided at a plurality of positions to perform sequential deposition;
track moving units that are respectively disposed within deposition ranges of the supply and deposition unit, are disposed below the base to be engaged with the base and to move therewith, are provided in the form of a caterpillar that converts a rotational motion into a linear motion at each of the plurality of deposition positions, and have track protrusions formed on an outer periphery thereof to be inserted into the base through-holes;
a track driving unit that is disposed at both ends of the track moving units in a lengthwise direction, and provides a rotational force to be converted for movement of the track moving units;
a tension adjusting unit that is disposed on upper and lower sides of each track moving unit under movement to adjust the tension of the track moving unit; and
a control unit that is connected to the track moving units and the tension adjusting units to control the movement and the tension.

2. The apparatus according to claim 1,
wherein the supply and deposition unit includes:
a base supply unit that supplies the base formed by lamination of a substrate, a support film, and the plurality of shadow masks to the track moving units for deposition;
the deposition sources disposed at the plurality of positions that are configured to discharge the vaporized materials for the respective deposition steps to perform the sequential deposition; and
a mask recovery unit that is disposed on a lower side between the plurality of deposition sources and is configured to recover each of the plurality of shadow masks that have completed the deposition in each stage.

3. The apparatus according to claim 1,
wherein the track moving unit includes:
a track body that is disposed in a movement range for each deposition step of the supply and deposition unit, is provided in the form of a caterpillar that moves in the lengthwise direction, and has track insertion holes that are formed in the form of plural through-holes spaced at a predetermined interval in the lengthwise direction to communicate with the base through-holes and are engaged with the track driving unit; and
the track protrusions that protrude at a plurality of positions at a predetermined interval on the outer surface of the track body, are disposed between the track insertion holes, and are engaged with the base through-holes to move together.

4. The apparatus according to claim 1,
wherein the track driving unit includes:
a track driving rotator that is disposed on one end side of the track moving unit in the lengthwise direction, has driving rotational protrusions that protrude in a radial manner on the outer periphery thereof and are inserted into and engaged with the track moving unit that communicates with the base through-holes, and is rotated for the conversion to the linear motion;
a track driven rotator that is disposed on the other end side of the track moving unit in the lengthwise direction, which is a position opposite to the track driving rotator, has driven rotational protrusions that protrude in a radial manner on the outer periphery thereof and are inserted into and engaged with the track moving unit that communicates with the base through-holes, and supports the rotation of the track driven rotator; and
a drive motor that is connected to one side of the track driving rotator, and supplies rotational power to the track driving rotator.

5. The apparatus according to claim 1, further comprising:
a driving gear rotator that is connected to one side of each of the plurality of track driving rotators, receives the rotational power, and rotates together with the track driving rotator: a driving shaft that is connected to the drive motor to transmit the rotational power of the drive motor, and is provided to pass through one side of the plurality of track driving rotators; and
a driving gear that is connected to the driving shaft at a plurality of positions to secure the same rotational speed, and is gear-engaged with the driving gear rotator to transmit the rotational power of the drive motor to the plurality of track driving rotators.

6. The apparatus according to claim 1,
wherein the tension control unit includes:
an upper support roller that is disposed at a plurality of positions spaced at a predetermined interval in an upper part of the caterpillar of the track moving unit under movement, and supports a lower side of the track moving unit that moves in a state of being engaged with the base to prevent sagging;
a down-regulating roller that is disposed in a lower part of the caterpillar of the track moving unit under movement, and presses an upper side of the track moving unit downward to adjust the tension according to change in the tension;
a down-regulating cylinder that is disposed above the down-regulating roller, and provides power for moving the down-regulating roller up and down according to the tension measured by the control unit;
an up-regulating roller that is disposed below the caterpillar of the track moving unit under movement, presses an upper side of the track moving unit upward to adjust the tension according to change in the tension, includes an up-regulating groove into which the track protrusions of the track moving unit engaged with the base are inserted at a central portion thereof; and
an up-regulating cylinder that is disposed below the up-regulating roller, and provides power for moving the up-regulating roller up and down according to the tension measured by the control unit.

7. The apparatus according to claim 6, further comprising:
an upper press roller that is disposed on the upper side of the caterpillar of the track moving unit under movement, is disposed above the upper support roller to press the upper side of the base of which the lower side is supported by the upper support roller, and has a press groove into which the track protrusions of the track moving unit inserted into the base are inserted at a central portion thereof.

8. The apparatus according to claim 1,
wherein the control unit includes:
a deposition movement speed sensor that is disposed on one side of the track moving unit under movement, and is provided to sense a movement speed of the base in each deposition step;
a tension sensor that is disposed on one side of the track moving unit under movement, and is provided to sense the tension on a movement path of the caterpillar; and
a control body that receives signals from the deposition movement speed sensor and the tension sensor, compares a predetermined speed for each deposition with the movement speed measured by the deposition movement speed sensor to control the track driving unit, and compares the tension value measured by the tension sensor with a predetermined tension value to control the tension control unit.

9. The apparatus according to claim 1, further comprising:
a sagging prevention unit that is disposed above the track driving unit to prevent sagging of the base.

10. The apparatus according to claim 9,
wherein the sagging prevention unit is disposed on the lower surface of the base, is located at each of opposite ends in the width direction around the base through-holes with which the track driving unit is engaged, and is made of a film adhesive that adheres to the upper surface of the track moving unit to prevent sagging.

11. The apparatus according to claim 9,
wherein the sagging prevention unit includes:
a metal strip that is disposed on the upper surface of the base at a central portion and both sides thereof in the width direction, and is made of a metal material for generating an attractive force by a magnetic force; and
a magnet body that is disposed above the track moving unit, is provided at a plurality of positions at a predetermined interval in the lengthwise direction, and applies the magnetic force to the metal strip provided on the base under movement to generate the attractive force in the central portion of the base for preventing sagging.

12. The apparatus according to claim 9,
wherein the sagging prevention unit includes:
a metal strip that is disposed on the upper surface of the base at a central portion and both sides thereof in the width direction, and is made of a metal material for generating an attractive force by a magnetic force;
a magnetic track body that is disposed in an overlay manner above the track moving unit to be moved in the form of a caterpillar, has magnetic track inserting holes that communicate with the base through-holes at positions spaced at a predetermined interval in the width direction, and is made of a magnetic material to generate an attractive force while moving above the metal strip; and
a magnetic track rotator that is disposed above the track driving unit, has magnetic track rotational protrusions that protrude in a radial manner on the outer periphery thereof and are inserted into the magnetic track insertion holes, and rotationally moves the caterpillar of the magnetic track body.
